(19) United States
(12) Patent Application Publication
(10) Pub. No.: US 2025/0079794 A1
(43) Pub. Date: Mar. 6, 2025

(54) HIGH-POWER SINGLE-WAVELENGTH SEMICONDUCTOR LASER HAVING MULTI-SEGMENT GRATING STRUCTURE

(71) Applicant: National Taiwan University of Science and Technology, Taipei City (TW)

(72) Inventors: SAN-LIANG LEE, Taipei City (TW); SULIKHAN SITI, Taipei (TW)

(21) Appl. No.: 18/391,724

(22) Filed: Dec. 21, 2023

(30) Foreign Application Priority Data
Aug. 31, 2023 (TW) 112133106

(51) Int. Cl. H01S 5/12; H01S 5/042

(52) U.S. Cl. CPC H01S 5/1215; H01S 5/04256; H01S 5/34

(57) ABSTRACT

A high-power single-wavelength semiconductor laser having multi-segment grating structure includes a cavity body, a gain layer, an electrode structure, a grating layer, an upper cladding layer, a lower cladding layer and a longitudinal waveguide structure. The cavity body has a resonant cavity, a reflective facet and an anti-reflective facet. The reflective and anti-reflective facets are respectively disposed to opposite first and second sides of the cavity body. The electrode structure is disposed on the resonant cavity. The grating layer in the resonant cavity includes a first sub-grating, a second sub-grating and no-corrugation segments, arranged in an alternate manner. The upper and lower cladding layers in the resonant cavity wrap the gain and grating layers to form a lateral waveguide structure. The longitudinal waveguide structure in the resonant cavity between the first side and the second side connects the first sub-grating, the second sub-grating and the no-corrugation segments.

### CROSS REFERENCE TO RELATED APPLICATION

This application claims the benefits of Taiwan application Serial No. 112133106, filed Aug. 31, 2023, the disclosures of which are incorporated by references herein in its entirety.

### TECHNICAL FIELD

The present disclosure relates in general to a semiconductor laser, and more particularly to a high-power single-wavelength semiconductor laser having multi-segment grating structure.

### BACKGROUND

In the art, co-packaging optics (CPO) technology has been widely used to manufacture optical switches used in the data center networking industry. A typical CPO module requires a high-power distributed feedback (DFB) laser to provide optical power for multiple silicon photonic (SiPh) modulators to reduce the number of optical fibers. Among them, since a distributed feedback laser based on a partially corrugated-grating (PCG) structure is provided with versatile advantages including a high single-mode yield (SMY), a low relative intensity noise (RIN), a high resistance to external feedback, simple manufacturing and so on, it has been widely used in the CPO modules and other silicon photonic optoelectronic integrated circuits. In addition, high-power lasers can also be used for optical sensing and satellite optical communications. As shown in FIG. 1, a PCG-DFB (Distributed feedback laser based on the partial corrugated grating structure) laser is schematically provided. This PCG-DFB laser 1 includes a substrate 10, a cavity body 11, a gain layer 12, an electrode structure 13, a grating layer 14, a buffer layer 15, an upper cladding layer 16A, a lower cladding layer 16B and a contact layer 17. The cavity body 11 has a resonant cavity 111, a reflective facet 112 and an anti-reflective facet 113. The electrode structure 13 includes a positive electrode 131 and a negative electrode 132. The grating layer 14 is spaced from a left sidewall of the cavity body 11. In the DFB laser currently used in optical communications and optical sensing systems, a uniformly distributed and periodic grating structure is generally included between two opposite end faces. Thus, in comparison with the existing DFB laser, the grating layer 14 of the PCG-DFB laser only covers part of the resonant cavity and part of the gain layer 12. Since a first-side reflective facet of the PCG-DFB laser usually produces a coating with a reflectivity of more than 90%, and the second-side anti-reflective facet thereof usually produces a coating with a reflectivity of less than 1%, so most of the output power is from the second side, so as to helpfully produce the high-power lasers. However, since the grating structure at the output end would reflect light back to the resonant cavity, the distribution of optical power in the resonant cavity would decrease with the position toward the second side, and thus the corresponding output power would therefore decrease. Therefore, the present disclosure proposes a new grating structure to improve the output power of the PCG-DFB laser and meet the requirements of the next generation of optical switch technology (requiring an output power up to 20 dBm or more).

### SUMMARY

In one embodiment of this disclosure, a high-power single-wavelength semiconductor laser having multi-segment grating structure includes a cavity body, a gain layer, an electrode structure, a grating layer, an upper cladding layer, a lower cladding layer and a longitudinal waveguide structure. The cavity body has a resonant cavity, a reflective facet and an anti-reflective facet. The resonant cavity is disposed in the cavity body. The reflective facet and the anti-reflective facet are respectively disposed to a first side and a second side of the cavity body, in which the first side is opposite to the second side. The gain layer is disposed in the resonant cavity. The electrode structure is disposed on the resonant cavity. The grating layer disposed in the resonant cavity includes a first sub-grating, a second sub-grating and a plurality of no-corrugation segments, in which the first sub-grating, the second sub-grating and the plurality of no-corrugation segments are alternately arranged. The upper cladding layer and the lower cladding layer, both disposed in the resonant cavity, wrap the gain layer and the grating layer to form a lateral waveguide structure. The longitudinal waveguide structure, extending along the resonant cavity between the first side and the second side, connects the first sub-grating, the second sub-grating and the plurality of no-corrugation segments.

In another embodiment of this disclosure, a high-power single-wavelength semiconductor laser having multi-segment grating structure includes a cavity body, a gain layer, an electrode structure, a grating layer, an upper cladding layer, a lower cladding layer and a longitudinal waveguide structure. The cavity body has a resonant cavity, a reflective facet and an anti-reflective facet. The resonant cavity is disposed in the cavity body. The reflective facet and the anti-reflective facet are respectively disposed to a first side and a second side of the cavity body, in which the first side is opposite to the second side. The gain layer is disposed in the resonant cavity. The electrode structure is disposed on the resonant cavity. The grating layer disposed in the resonant cavity includes a plurality of sub-gratings and a plurality of no-corrugation segments, in which the plurality of sub-gratings and the plurality of no-corrugation segments are alternately arranged. The upper cladding layer and the lower cladding layer, both disposed in the resonant cavity, wrap the gain layer and the grating layer to form a lateral waveguide structure. The longitudinal waveguide structure, extending along the resonant cavity between the first side and the second side, connects the plurality of sub-gratings and the plurality of no-corrugation segments.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a schematic view of a conventional PCG-DFB (Distributed feedback laser based on the partial corrugated grating structure) laser;

FIG. 2 is a schematic view of a first embodiment of the high-power single-wavelength semiconductor laser having multi-segment grating structure in accordance with this disclosure;

FIG. 3 illustrates schematically simulation results (Output power vs. Direct current) of the first embodiment of the high-power single-wavelength semiconductor laser having multi-segment grating structure in accordance with this disclosure;

FIG. 4 illustrates schematically simulation results (Power vs. Position) of the first embodiment of the high-power single-wavelength semiconductor laser having multi-segment grating structure in accordance with this disclosure;

FIG. 5 is a schematic top view of FIG. 2;

FIG. 6 is a schematic top view of a second embodiment of the high-power single-wavelength semiconductor laser having multi-segment grating structure in accordance with this disclosure;

FIG. 7 is a schematic top view of a third embodiment of the high-power single-wavelength semiconductor laser having multi-segment grating structure in accordance with this disclosure;

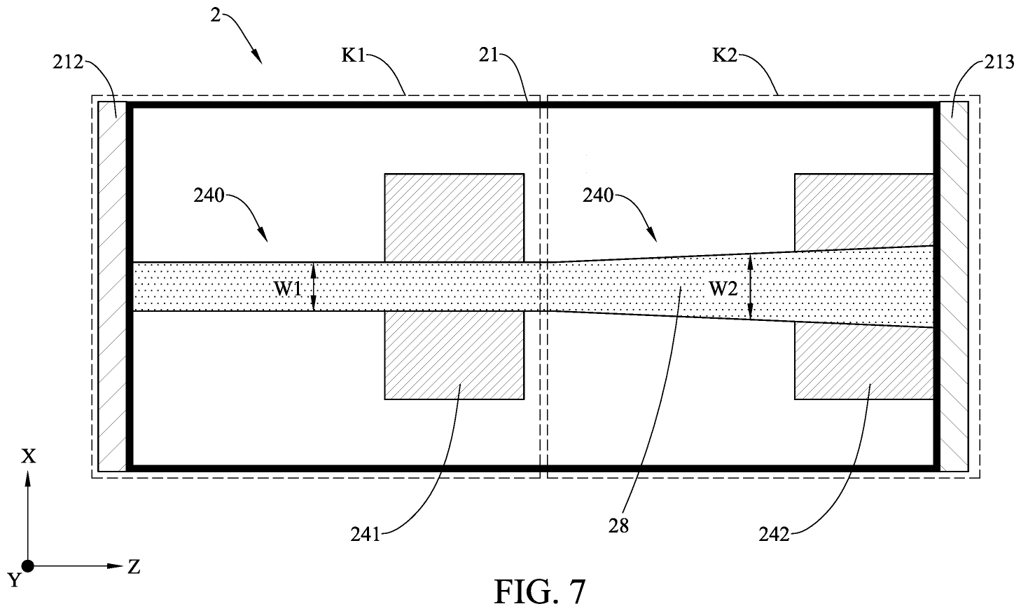

FIG. 8 is a schematic view of a fourth embodiment of the high-power single-wavelength semiconductor laser having multi-segment grating structure in accordance with this disclosure;

FIG. 9A is a schematic view of a fifth embodiment of the high-power single-wavelength semiconductor laser having multi-segment grating structure in accordance with this disclosure;

FIG. 9B is another schematic view of FIG. 9A; and

FIG. 10 is a schematic top view of FIG. 9A.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The following will refer to the related drawings to illustrate embodiments of the high-power single-wavelength semiconductor laser having multi-segment grating structure according to the present disclosure. For the sake of clarity and convenience of illustration, the size and proportion of the components in the drawings may be exaggerated or represented in a reduced size. In the following description and/or claims, when an element is “connected” or “coupled” to another element, it may be directly connected or coupled to the other element or through intervening elements. When “directly connected” or “directly coupled” to another element, there are no intervening elements. Similarly, any other words used to describe the relationship between elements or layers should be interpreted in the same way. To facilitate understanding, the same components in the following embodiments are described with the same symbols.

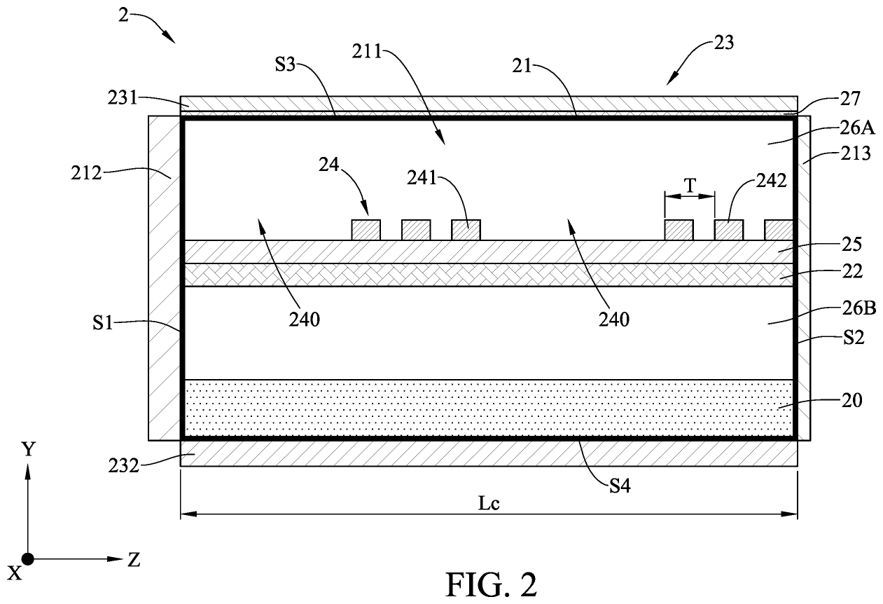

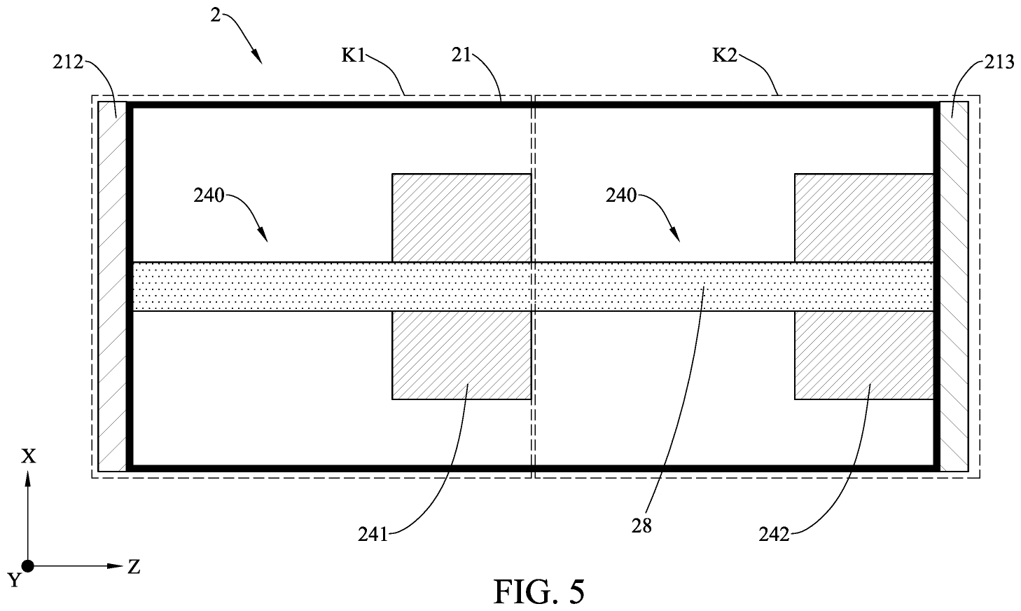

Referring to FIG. 2, a schematic view of a first embodiment of the high-power single-wavelength semiconductor laser having multi-segment grating structure in accordance with this disclosure is shown. In this embodiment, the semiconductor laser 2 includes a substrate 20, a cavity body 21, a gain layer 22, an electrode structure 23, a grating layer 24, a buffer layer 25, an upper cladding layer 26A, a lower cladding layer 26B, a contact layer 27 and a longitudinal waveguide structure 28 (shown in FIG. 5 as follows).

The cavity body 21 has a resonant cavity 211, a reflective facet 212 and an anti-reflective facet 213. The resonant cavity 211 is disposed in the cavity body 21. The reflective facet 212, disposed to a first side S1 of the cavity body 21, is a highly-reflective coated layer. The anti-reflective facet 213, disposed to a second side S2 of the cavity body 21, is an anti-reflective coated layer. The first side S1 is located by opposing the second side S2, and the second side S2 is a light-emitting plane.

The gain layer 22 (an active region) is disposed in the resonant cavity 211. In one exemplary example, the gain layer 22 can a structure having quantum wells, multiple quantum wells (MQW) or quantum dots.

The electrode structure 23, disposed on the cavity body 21, is connected with an electric current source (not shown in the figure). The electrode structure 23 includes a positive electrode 231 and a negative electrode 232. The positive electrode 231 and the negative electrode 232 are disposed to a third side S3 and a fourth side S4 of the cavity body 21, respectively. The third side S3 is opposite to the fourth side S4.

The grating layer 24 is disposed on the gain layer 22 in the resonant cavity 211. The grating layer 24 includes a first sub-grating 241, a second sub-grating 242 and a plurality of no-corrugation segments 240 (two shown in this embodiment). The first sub-grating 241, the second sub-grating 242 and the plurality of no-corrugation segments 240 are alternately arranged. In another embodiment, the grating layer 24 can be disposed under the gain layer 22.

The upper cladding layer 26A and the lower cladding layer 26B are two semiconductor structures disposed in the resonant cavity 211. The upper cladding layer 26A is disposed above the grating layer 24, while the lower cladding layer 26B is disposed below the gain layer 22, such that the upper cladding layer 26A and the lower cladding layer 26B can wrap the grating layer 24 and the gain layer 22 so as to form a lateral waveguide structure. The substrate 20 is disposed under the lower cladding layer 26B in the resonant cavity 211.

The gain layer is usually formed with multiple layers of different material composition, including multiple quantum well or quantum dot structures sandwiched between the separate confinement layers. The multi-layer gain structure can be arranged to reduce the confinement factor and intrinsic loss and then increase the slope efficiency of the output power-vs-current curve of the laser. An additional layer can also be inserted in the lower cladding layer to further reduce the confinement factor and intrinsic loss.

The contact layer 27, disposed between the positive electrode 231 and the upper cladding layer 26A, is made of a semiconductor material capable of reducing contact resistance between the electrode 231 and the upper cladding layer 26A.

The buffer layer 25, is a semiconductor structure disposed between the grating layer 24 and the gain layer 22. The buffer layer 25 can serve as a structure for modulating a grating coupling coefficient or buffering an etching process.

The longitudinal waveguide structure 28, extending along the resonant cavity 211, is disposed between the first side S1 and the second side S2. The longitudinal waveguide structure 28 connects the first sub-grating 241, the second sub-grating 242 and the plurality of no-corrugation segments 240. In a lower left corner of FIG. 2, a transverse direction X, a lateral direction Y and the longitudinal direction Z are illustrated.

When an electric current source is applied to the electrode structure 23 in a forward bias manner, electrons and electric holes of the gain layer 22 would be coupled to radiate photons. These photons would be reflected at the grating layer 24 to form single-wavelength feedbacked light, and further to generate resonance inside the resonant cavity 211 so as to produce corresponding single-wavelength output light LS.

In this embodiment, the grating layer 24 of the semiconductor laser 2 is a multi-segment grating structure. As described above, the grating layer 24 includes the first sub-grating 241 and the second sub-grating 242. Each of the first sub-grating 241 and the second sub-grating 242 is furnished with the no-corrugation segment 240. As shown, one no-corrugation segment 240 exists between the first sub-grating 241 and the first side S1 of the cavity body 2, and another no-corrugation segment 240 exists between the second sub-grating 242 and the second side S2 of the cavity body 2. Preferably, the first sub-grating 241 and the second sub-grating 242 are structured according to the same period T, and the wavelength LS and the period T of the output light would be proportional. In this embodiment, the first sub-grating 241 and the second sub-grating 242 have the same length.

The aforementioned multi-segment grating structure can effectively make the distribution of the light field more uniform in the resonant cavity body 21 of the semiconductor laser 2, such that the light intensity (i.e., photon density) from the light-emitting plane (i.e., anti-reflective facet 213) of the cavity body 21 of the semiconductor laser 2 can be raised. Thus, the output power of the semiconductor laser 2 can be significantly improved.

Of course, this embodiment is only for illustration and not limiting the scope of this disclosure, and equivalent modifications or changes made according to the high-power single-wavelength semiconductor laser having multi-segment grating structure of the aforementioned embodiment should be still included within the patent scope of this disclosure.

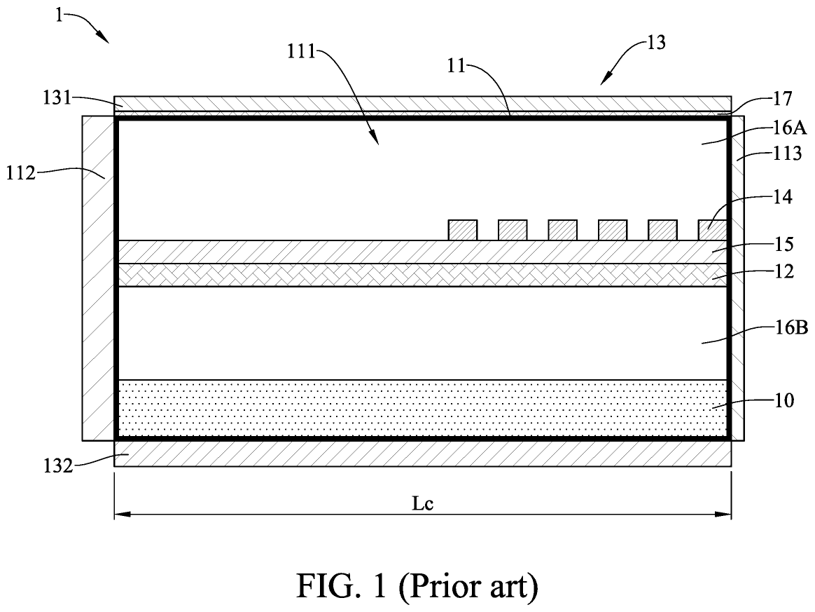

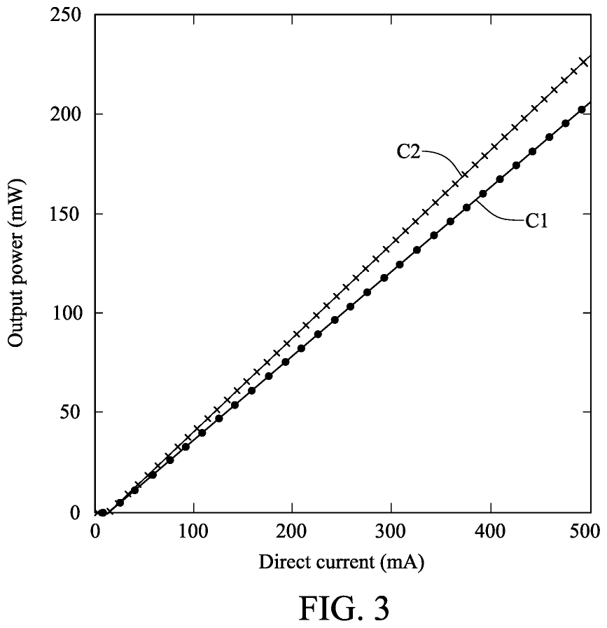

Referring to FIG. 3, simulation results (Output power vs. Direct current) of the first embodiment of the high-power single-wavelength semiconductor laser having multi-segment grating structure in accordance with this disclosure are illustrated schematically. As shown, curve C1 stands for the simulation results obtained from a current PCG-DFB laser 1 (as shown in FIG. 1), and curve C2 stands for the simulation results obtained from the first embodiment of the high-power single-wavelength semiconductor laser having multi-segment grating structure 2 in accordance with this disclosure. In the figure, the horizontal axis stands for the applied direct current, and the vertical axis stands for the corresponding output power. Both the aforementioned simulation results are listed in Table 1 as follows,

| | Semiconductor laser 1 | Semiconductor laser 2 |
|---|---|---|
| Parameters | Simulation results | Simulation results |
| Iₜₕ (mA) | 13 | 15 |
| Pₚₑₐₖ (mW) | 206.211 | 228.2302 |
| SE (mW/mA) | 0.4234 | 0.4706 |

In the table, Iₜₕ stands for the threshold current value, Pₚₑₐₖ stands for the power peak value, and SE stands for the slope efficiency.

As shown, the embodiment of the high-power single-wavelength semiconductor laser having multi-segment grating structure 2 is confirmed to be able to provide greater output powers and performance.

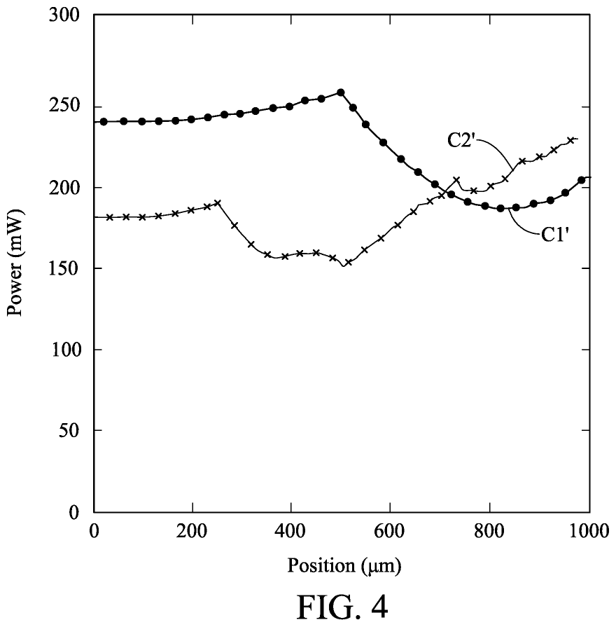

Referring to FIG. 4, simulation results (Power vs. Position) of the first embodiment of the high-power single-wavelength semiconductor laser having multi-segment grating structure in accordance with this disclosure are illustrated schematically. As shown, curve C1′ stands for the simulation results obtained from the aforementioned PCG-DFB laser 1 (as shown in FIG. 1), and curve C2′ stands for the simulation results obtained from the first embodiment of the high-power single-wavelength semiconductor laser having multi-segment grating structure 2 in accordance with this disclosure. In the figure, the vertical axis stands for the applied power, and the horizontal axis stands for the corresponding position. The cavity body (11) 21 has a length Lc of 1000 μm. The aforementioned position is referred to the position of the first side S1 of the cavity body (11) 21 (i.e., the position of the first side S1 of the cavity body (11) 21 is the origin).

As shown, the aforementioned multi-segment grating structure can effectively distribute uniformly the light field of resonant cavities 211 in the cavity body 21 of the semiconductor laser 2, such that the light intensity (i.e., photon density) from the light-emitting plane of the cavity body 21 of the semiconductor laser 2 can be raised approximately by 11.4%. Thus, the output power of the semiconductor laser 2 can be significantly improved to resolve current technical problems. Thereupon, the semiconductor laser 2 provided in this disclosure can meet technical requirements for next generation optical switches.

Of course, this embodiment is only for illustration and not limiting the scope of this disclosure, and equivalent modifications or changes made according to the high-power single-wavelength semiconductor laser having multi-segment grating structure of the aforementioned embodiment should be still included within the patent scope of this disclosure.

Referring to FIG. 5, a schematic top view of FIG. 2 is shown. As illustrated, the longitudinal waveguide structure 28 is extended along the resonant cavity 211 (i.e., the longitudinal direction Z) between the first side S1 and the second side S2. The longitudinal waveguide structure 28 connects the first sub-grating 241, the second sub-grating 242 and the plurality of no-corrugation segments 240. In a lower left corner of FIG. 5, the transverse direction X, the lateral direction Y and the longitudinal direction Z are illustrated. In this embodiment, the longitudinal waveguide structure 28 includes a first section K1 and a second section K2. The first section K1 includes a reflective facet 212, a no-corrugation segment 240 and a first sub-grating 241. The second section K2 includes another no-corrugation segment 240, a second sub-grating 242 and an anti-reflective facet 213. In this embodiment, a waveguide structure of the first section K1 is identical to that of the second section K2.

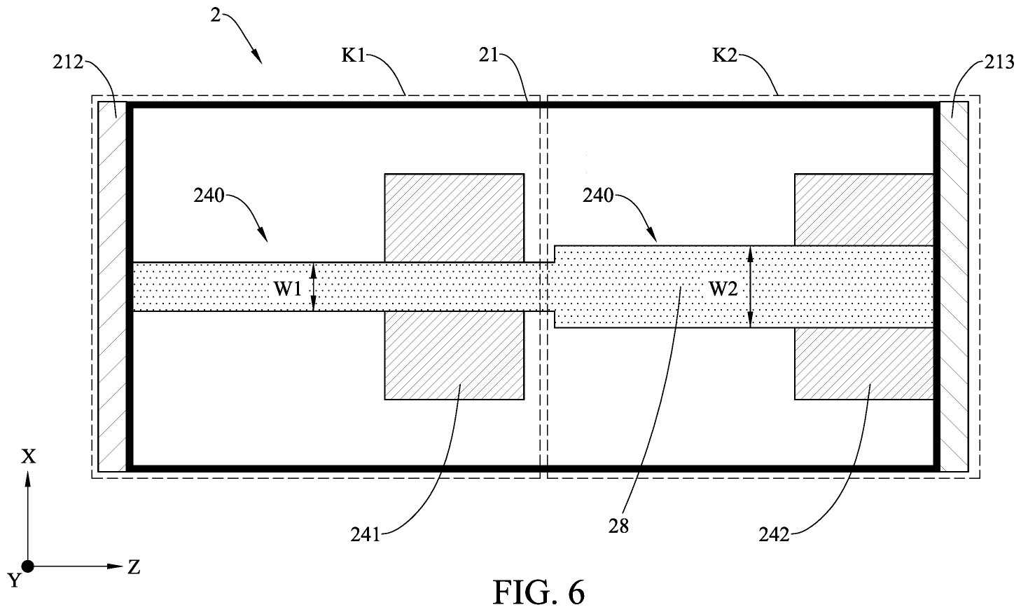

Referring to FIG. 6, a schematic top view of a second embodiment of the high-power single-wavelength semiconductor laser having multi-segment grating structure in accordance with this disclosure is shown. In this embodiment, the longitudinal waveguide structure 28 is extended along the resonant cavity 211 (i.e., the longitudinal direction Z) between the first side S1 and the second side S2. The longitudinal waveguide structure 28 connects the first sub-grating 241, the second sub-grating 242 and the plurality of no-corrugation segments 240. Similarly, the longitudinal waveguide structure 28 includes a first section K1 and a second section K2. Different to the previous embodiment, in this embodiment, a width W2 of the waveguide structure of the second section K2 is greater than a width W1 of the waveguide structure of the first section K1. Here, the width W1 or W2 is the width in the transverse direction X.

As described above, the width W2 of the waveguide structure of the second section K2 is greater than the width W1 of the waveguide structure of the first section K1, and thus the longitudinal waveguide structure 28 is understood to be furnished with a multi-segment waveguide structure. This multi-segment waveguide structure can contribute to improve the power, and further to raise the output power of the semiconductor laser 2.

Of course, this embodiment is only for illustration and not limiting the scope of this disclosure, and equivalent modifications or changes made according to the high-power single-wavelength semiconductor laser having multi-segment grating structure of the aforementioned embodiment should be still included within the patent scope of this disclosure.

Referring to FIG. 6, a schematic top view of a third embodiment of the high-power single-wavelength semiconductor laser having multi-segment grating structure in accordance with this disclosure is shown. In this embodiment, the longitudinal waveguide structure 28 is extended along the resonant cavity 211 (i.e., the longitudinal direction Z) between the first side S1 and the second side S2. The longitudinal waveguide structure 28 connects the first sub-grating 241, the second sub-grating 242 and the plurality of no-corrugation segments 240. Similarly, the longitudinal waveguide structure 28 includes a first section K1 and a second section K2. Different to the previous embodiment, in this embodiment, the waveguide structure of the first section K1 is different to that of the second section K2. The width W2 of the waveguide structure of the second section K2 varies in the longitudinal direction Z. As illustrated, the width W2 of the waveguide structure of the second section K2 is gradually increased in the longitudinal direction Z.

As described above, the longitudinal waveguide structure 28 has a tapering waveguide structure. In this embodiment, the width W2 of the waveguide structure of the second section K2 is extended in the longitudinal direction Z in a gradually wider and wider manner. As such, the multi-segment waveguide structure can also provide an enhanced power, and thus the output power of the semiconductor laser 2 can be further improved.

Of course, this embodiment is only for illustration and not limiting the scope of this disclosure, and equivalent modifications or changes made according to the high-power single-wavelength semiconductor laser having multi-segment grating structure of the aforementioned embodiment should be still included within the patent scope of this disclosure.

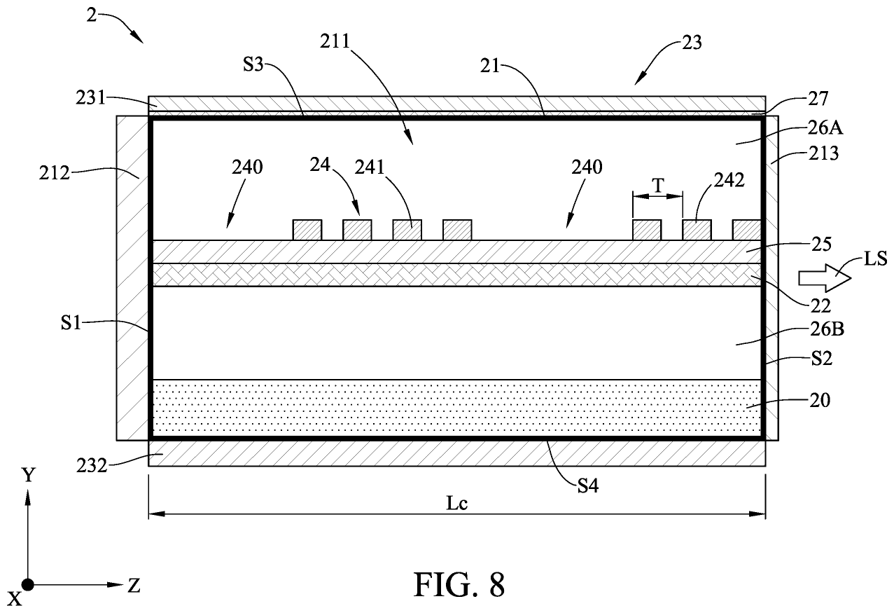

Referring to FIG. 8, a schematic view of a fourth embodiment of the high-power single-wavelength semiconductor laser having multi-segment grating structure in accordance with this disclosure is shown. In this embodiment, the semiconductor laser 2 includes a substrate 20, a cavity body 21, a gain layer 22, an electrode structure 23, a grating layer 24, a buffer layer 25, an upper cladding layer 26A, a lower cladding layer 26B, a contact layer 27 and a longitudinal waveguide structure 28 (similar to the longitudinal waveguide structure 28 shown in FIG. 5).

The cavity body 21 has a resonant cavity 211, a reflective facet 212 and an anti-reflective facet 213. The resonant cavity 211 is disposed in the cavity body 21. The reflective facet 212 is disposed to a first side S1 of the cavity body 21, and the anti-reflective facet 213 is disposed to a second side S2 of the cavity body 21, in which the second side S2 is a light-emitting plane, and the first side S1 is located by opposing the second side S2.

The gain layer 22 is disposed in the resonant cavity 211.

The electrode structure 23, disposed on the cavity body 21, is connected with an electric current source (not shown in the figure). The electrode structure 23 includes a positive electrode 231 and a negative electrode 232. The positive electrode 231 and the negative electrode 232 are disposed to a third side S3 and a fourth side S4 of the cavity body 21, respectively. The third side S3 is opposite to the fourth side S4.

The grating layer 24 is disposed on the gain layer 22 in the resonant cavity 211. The grating layer 24 includes a first sub-grating 241, a second sub-grating 242 and a plurality of no-corrugation segments 240 (two shown in this embodiment). The first sub-grating 241, the second sub-grating 242 and the plurality of no-corrugation segments 240 are alternately arranged. In another embodiment, the grating layer 24 can be disposed under the gain layer 22.

The upper cladding layer 26A is disposed on the grating layer 24, while the lower cladding layer 26B is disposed on the gain layer 22, such that the upper cladding layer 26A and the lower cladding layer 26B can wrap the grating layer 24 and the gain layer 22 so as to form a lateral waveguide structure. The substrate 20 is disposed under the lower cladding layer 26B in the resonant cavity 211.

The contact layer 27, disposed between the positive electrode 231 and the upper cladding layer 26A.

The buffer layer 25 is disposed between the grating layer 24 and the gain layer 22.

The longitudinal waveguide structure 28, extending along the resonant cavity 211 between the first side S1 and the second side S2, connects the first sub-grating 241, the second sub-grating 242 and the plurality of no-corrugation segments 240.

In this embodiment, the grating layer 24 of the semiconductor laser 2 is a multi-segment grating structure. As described above, the grating layer 24 includes the first sub-grating 241, the second sub-grating 242 and two no-corrugation segments 240. The first sub-grating 241, the second sub-grating 242 and the two no-corrugation segments 240 are alternately arranged. Each of the first sub-grating 241 and the second sub-grating 242 is furnished with the no-corrugation segment 240. The no-corrugation segment 240 exists between the first sub-grating 241 and the first side S1 of the cavity body 21, and the second sub-grating 242 is connected with the second side S2 of the cavity body 21. Different to the aforementioned embodiments, in this embodiment, the first sub-grating 241 and the second sub-grating 242 have different lengths. In particular, the length of the second sub-grating 242 is greater than that of the first sub-grating 241.

As described above, the grating layer 24 of the semiconductor laser 2 includes a first sub-grating 241 and a second sub-grating 242, and a length of the second sub-grating 242 is greater than that of the first sub-grating 241, such that an asymmetric cascade and multi-segment grating structure can be formed. Through the foregoing grating layer 24, the semiconductor laser 2 can be furnished with superior robustness, and can be produced by contributing a high single-mode yield under high temperature. In addition, the side-mode suppression ratio (SMSR) of the semiconductor laser 2 can be substantially improved, and the endurance against foreign feedback can be up lifted. Thereupon, the foregoing asymmetric cascade and multi-segment grating structure can be implemented to optimize significantly the performance of the semiconductor laser 2, such that the semiconductor laser 2 can meet practical application requirements.

In another embodiment, the length of the first sub-grating 241 can be greater than that of the second sub-grating 242. In this disclosure, lengths of the first sub-grating 241 and the second sub-grating 242 can be adjusted according to practical needs, but not limited thereto.

Of course, this embodiment is only for illustration and not limiting the scope of this disclosure, and equivalent modifications or changes made according to the high-power single-wavelength semiconductor laser having multi-segment grating structure of the aforementioned embodiment should be still included within the patent scope of this disclosure.

It is worth to mention that the output power of the existing PCG-DFB laser requires further improvement so as to meet needs of next generation optical switch technology or other applications. According to the embodiments of this disclosure, the grating layer of the semiconductor laser includes the first sub-grating, the second sub-grating and plural no-corrugation segments. In particular, the first sub-grating, the second sub-grating and the plurality of no-corrugation segments are alternately arranged so as to form the multi-segment grating structure. The foregoing multi-segment grating structure can effectively and uniformly distribute the light field of the resonant cavity of the cavity body of the semiconductor laser, so that the light intensity (photon density) of the light-emitting plane of the cavity body of the semiconductor laser can be substantially improved. Thereupon, the output power of the semiconductor laser provided in this disclosure can be effectively improved to meet technical requirements for next generation optical switches.

In addition, according to the embodiments of this disclosure, the grating structure of the semiconductor laser includes the first sub-grating, the second sub-grating and plural no-corrugation segments. The first sub-grating, the second sub-grating and the plurality of no-corrugation segments are alternately arranged, and the first sub-grating and the second sub-grating have different lengths so as to form an asymmetric cascade grating structure. With such an asymmetric cascade grating structure, the semiconductor laser can provide considerable robustness, and the production of the semiconductor laser can keep at a high single-mode yield under high temperature. In addition, the side-mode suppression ratio of the semiconductor laser can be improved, and better endurance against foreign feedback can be provided. Thus, the performance of the semiconductor laser can be further optimized to meet practical requirements.

In addition, according to the embodiments of this disclosure, longitudinal the waveguide structure of the semiconductor laser can have the multi-segment waveguide structure or the tapering waveguide structure. The foregoing waveguide structure can effectively increase the power, and thus the output power of the semiconductor laser can be further improved to meet technical requirements for next generation optical switches.

Furthermore, according to the embodiment of this disclosure, the design of the semiconductor laser is simple, so the desired effect can be achieved without greatly increasing the cost. Thus, the semiconductor laser of this disclosure can achieve higher practicability and better meet the needs of practical applications.

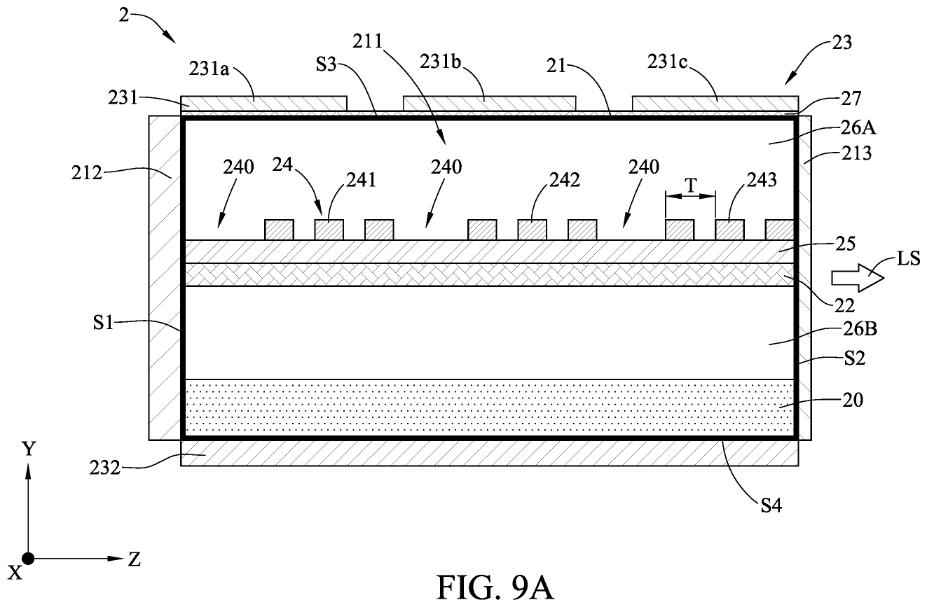

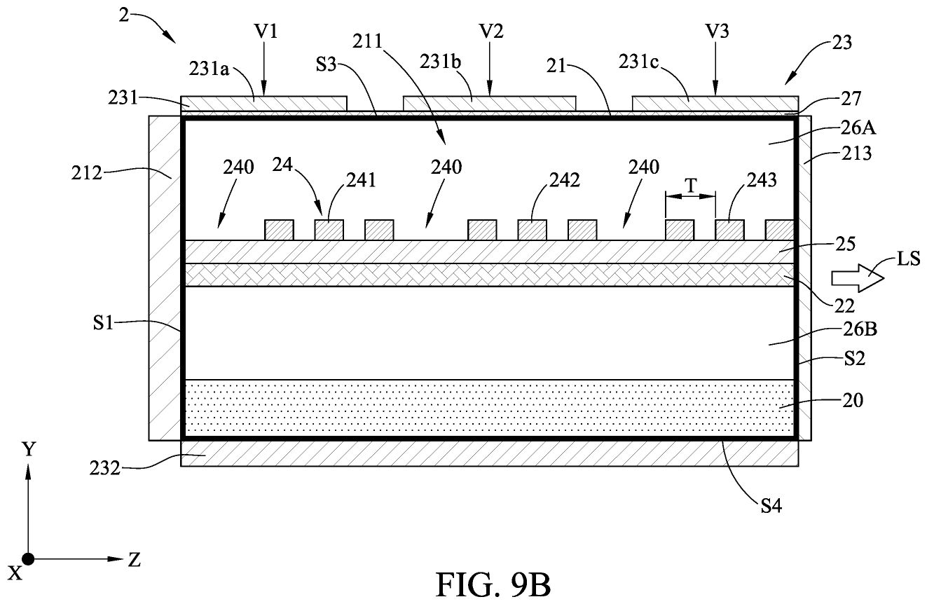

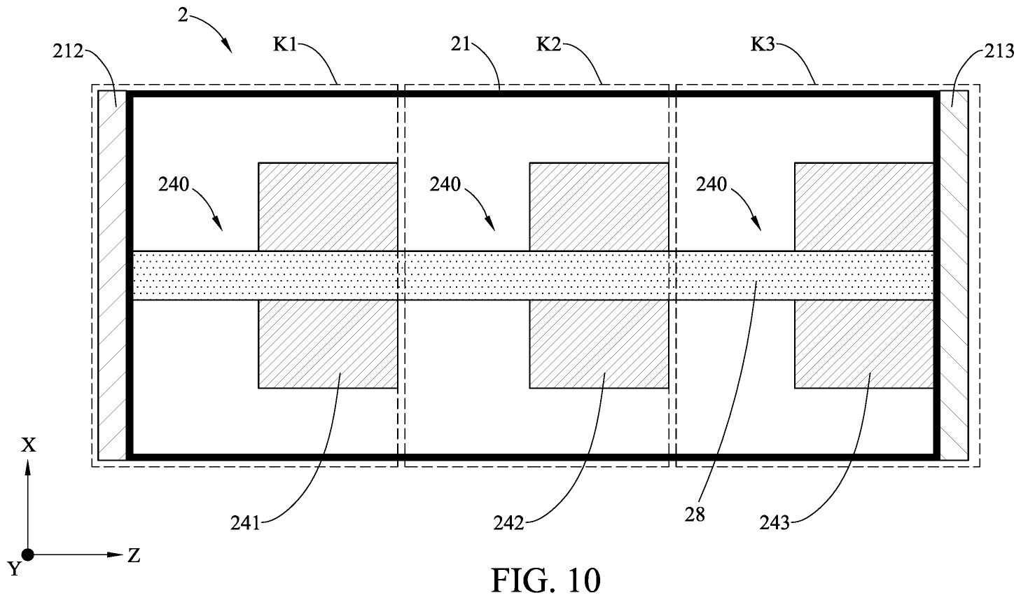

Refer to FIG. 9A, FIG. 9B and FIG. 10; where FIG. 9A is a schematic view of a fifth embodiment of the high-power single-wavelength semiconductor laser having multi-segment grating structure in accordance with this disclosure, FIG. 9B is another schematic view of FIG. 9A, and FIG. 10 is a schematic top view of FIG. 9A. In this embodiment, the semiconductor laser 2 includes a cavity body 21, a gain layer 22, an electrode structure 23, a grating layer 24, a buffer layer 25, an upper cladding layer 26A, a lower cladding layer 26B, a contact layer 27 and a longitudinal waveguide structure 28.

The cavity body 21 has a resonant cavity 211, a reflective facet 212 and an anti-reflective facet 213. The resonant cavity 211 is disposed in the cavity body 21. The reflective facet 212 is disposed to a first side S1 of the cavity body 21, and the anti-reflective facet 213 is disposed to a second side S2 of the cavity body 21, in which the second side S2 is a light-emitting plane, and the first side S1 is located by opposing the second side S2.

The gain layer 22 is disposed in the resonant cavity 211.

The electrode structure 23 is disposed on the cavity body 21. Different to the aforementioned embodiments, in this embodiment, the electrode structure 23 are connected with three electric current sources (not shown in the figure), and includes three positive electrodes 231a, 231b, 231c and one negative electrode 232. The three positive electrodes 231a, 231b, 231c and the negative electrode 232 are individually disposed to a third side S3 and a fourth side S4 of the cavity body 21, in which the third side S3 is opposite to the fourth side S4. Though this embodiment shows three positive electrodes, yet the amount of the positive electrodes of this disclosure can be two or more, and not limited thereto. Also, in another embodiment, the amount of the negative electrodes can be two or more. In particular, according to this disclosure, the amount of the negative electrodes can be equal to that of the positive electrodes, such that the plurality of negative electrodes can be arranged to correspond individual positive electrodes.

The grating layer 24 is disposed above the gain layer 22 in the resonant cavity 211.

The upper cladding layer 26A is disposed on the grating layer 24, while the lower cladding layer 26B is disposed on the gain layer 22, such that the upper cladding layer 26A and the lower cladding layer 26B can be integrated o wrap the grating layer 24 and the gain layer 22 so as to form a lateral waveguide structure. In addition, a substrate 20 in the resonant cavity 211 is disposed under the lower cladding layer 26B.

The contact layer 27 is disposed between the positive electrode 231 and the upper cladding layer 26A.

The buffer layer 25 is a semiconductor structure disposed between the grating layer 24 and the gain layer 22.

Different to the aforementioned embodiments, in this embodiment, the grating layer 24 includes a first sub-grating 241, a second sub-grating 242, a third sub-grating 243 and three no-corrugation segments 240. One no-corrugation segment 240 is located between the first sub-grating 241 and the first side S1 of the cavity body 21, another no-corrugation segment 240 is located between the first sub-grating 241 and the second sub-grating 242, and the third no-corrugation segment 240 is located between the second sub-grating 242 and the third sub-grating 243. Preferably, the first sub-grating 241, the second sub-grating 242 and the third sub-grating 243 have the same length.

As described above, the grating layer 24 of this disclosure may include more sub-gratings. Similarly, the aforementioned multi-segment grating structure can effectively distribute uniformly the light field of resonant cavities in the cavity body 21 of the semiconductor laser 2, such that the light intensity (i.e., photon density) from the light-emitting plane of the cavity body 21 of the semiconductor laser 2 can be substantially improved.

In addition, the forward bias (a voltage) applied to the plurality of positive electrodes 231a, 231b, 231c and the negative electrode 232 is increased in the longitudinal direction Z extending from the first side S1 to the second side S2. In other words, if a first voltage V1 is the forward bias applied to the positive electrode 231a and the negative electrode 232, a second voltage V2 is the forward bias applied to the positive electrode 231b and the negative electrode 232, and a third voltage V3 is the forward bias applied to the positive electrode 231c and the negative electrode 232, then the third voltage V3 is greater than the second voltage V2, and the second voltage V2 is greater than the first voltage V1. The aforementioned electrode structure 23 can raise up the light intensity (photon density) of the light-emitting plane of the cavity body 21 of the semiconductor laser 2 so as further to improve the output power of the semiconductor laser 2.

In addition, in this embodiment, the longitudinal waveguide structure 28 can include a first section K1, a second section K2 and a third section K3. The first section K1 includes the reflective facet 212, the no-corrugation segment 240 and the sub-grating 241. The second section K2 includes the no-corrugation segment 240 and the sub-grating 242. Third section K3 includes the no-corrugation segment 240, the sub-grating 243 and the anti-reflective facet 213. In this embodiment, waveguide structures of the first section K1, the second section K2 and the third section K3 are identical. However, in another embodiment, the longitudinal waveguide structure 28 may include the aforementioned multi-segment waveguide structure or the tapering waveguide structure.

In another embodiment, the grating layer 24 may include at least three sub-gratings. Namely, the longitudinal waveguide structure 28 can include at least three sections. A first section can include the reflective facet 212, at least one no-corrugation segment 240 and at least one sub-grating. A last section can include at least one no-corrugation segment 240, at least one sub-grating and the anti-reflective facet 213. In any of the rest of the sections, at least one no-corrugation segment 240 and at least one sub-grating are included. In this disclosure, the waveguide structures of different sections can be the same or different.

In another embodiment, the grating layer 24 can include at least three sub-gratings. One no-corrugation segment 240 can be sandwiched by two neighboring sub-gratings. The number of the sub-gratings shall be adjusted according to practical needs, so that the performance of the semiconductor laser 2 can be optimized. Lengths of different no-corrugation segments 240 can be equal or non-equal. In further one embodiment, the electrode structure 23 may include at least three positive electrodes, while the number of the positive electrodes is adjustable per practical requirements, such that the performance of the semiconductor laser 2 can be optimized. In another embodiment, one of the plurality of sub-gratings may present the maximum length (longer than any of other sub-gratings).

Of course, this embodiment is only for illustration and not limiting the scope of this disclosure, and equivalent modifications or changes made according to the high-power single-wavelength semiconductor laser having multi-segment grating structure of the aforementioned embodiment should be still included within the patent scope of this disclosure.

In summary, according to embodiments of this disclosure, the grating structure of the semiconductor laser includes the first sub-grating, the second sub-grating and plural no-corrugation segments, and the first sub-grating, the second sub-grating and the no-corrugation segments are alternately arranged to form the multi-segment grating structure. This multi-segment grating structure can effectively and uniformly distribute the light field of the resonant cavity in the cavity body of the semiconductor laser, such that the light intensity (photon density) on the light-emitting plane of the cavity body of the semiconductor laser can be enhanced. As such, the output power of the semiconductor laser can be improved as well to meet technical demands of the nest generation optical switches.

Further, according to embodiments of this disclosure, the grating structure of the semiconductor laser includes the first sub-grating, the second sub-grating and plural no-corrugation segments, and the first sub-grating, the second sub-grating and the no-corrugation segments are alternately arranged to form the multi-segment grating structure. In particular, the first sub-grating and the second sub-grating have different lengths so as to form the asymmetric cascade grating structure. Through this asymmetric cascade grating structure, the robustness of the semiconductor laser can be further improved, and the single-mode yield of the semiconductor laser at high temperature can be well upheld. In addition, the side-mode suppression ratio of the semiconductor laser can be also improved to provide better endurance against foreign feedback. Thereupon, the performance of the semiconductor laser can be further optimized to meet practical application needs.

In addition, according to embodiments of this disclosure, the longitudinal waveguide structure of the semiconductor laser can adopt the multi-segment waveguide structure or the tapering waveguide structure to effectively promote the power of the semiconductor laser. Also, the output power of the semiconductor laser can be further uplifted to match the demands of the nest generation switched.

In addition, according to embodiments of this disclosure, the electrode structure of the semiconductor laser may include plural positive electrodes and plural negative electrodes, disposed to the third side and the fourth side of the cavity body of the semiconductor laser, respectively. The voltage between the positive electrode and the corresponding negative electrode can be increased in the first direction. The aforementioned electrode structure can improve the light intensity (photon density) of the cavity body of the semiconductor laser, and thus the output power of the semiconductor laser can be improved further.

Furthermore, according to embodiments of this disclosure, the design of the semiconductor laser is simple, so the desired effect can be achieved without greatly increasing the cost. Thus, the semiconductor laser of this disclosure can achieve higher practicability and wider applications.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A high-power single-wavelength semiconductor laser having multi-segment grating structure, comprising:
a cavity body, having a resonant cavity, a reflective facet and an anti-reflective facet, the resonant cavity being disposed in the cavity body, the reflective facet and the anti-reflective facet being respectively disposed to a first side and a second side of the cavity body, the first side being opposite to the second side;
a gain layer, disposed in the resonant cavity;
an electrode structure, disposed on the cavity body;
a grating layer, disposed in the resonant cavity, including a first sub-grating, a second sub-grating and a plurality of no-corrugation segments, the first sub-grating, the second sub-grating and the plurality of no-corrugation segments being alternately arranged;
an upper cladding layer and a lower cladding layer, disposed in the resonant cavity, wrapping the gain layer and the grating layer to form a lateral waveguide structure; and
a longitudinal waveguide structure, extending along the resonant cavity between the first side and the second side, connecting the first sub-grating, the second sub-grating and the plurality of no-corrugation segments.

2. The high-power single-wavelength semiconductor laser having multi-segment grating structure of claim 1, wherein lengths of the first sub-grating and the second sub-grating are the same or different.

3. The high-power single-wavelength semiconductor laser having multi-segment grating structure of claim 1, wherein the second sub-grating and the second side are connected with a passive waveguide.

4. The high-power single-wavelength semiconductor laser having multi-segment grating structure of claim 1, further including a buffer layer disposed between the grating layer and the gain layer, the grating layer being parallel to the gain layer.

5. The high-power single-wavelength semiconductor laser having multi-segment grating structure of claim 1, wherein the first sub-grating and the second sub-grating have the same period.

6. The high-power single-wavelength semiconductor laser having multi-segment grating structure of claim 1, further including a contact layer disposed between the positive electrode and the upper cladding layer.

7. The high-power single-wavelength semiconductor laser having multi-segment grating structure of claim 1, wherein the electrode structure includes a positive electrode and a negative electrode, the positive electrode and the negative electrode are disposed respectively to a third side and a fourth side of the cavity body, and the third side is opposite to the fourth side.

8. The high-power single-wavelength semiconductor laser having multi-segment grating structure of claim 1, wherein the electrode structure includes a plurality of positive electrodes and a plurality of negative electrodes, the plurality of positive electrodes and the plurality of negative electrodes are respectively disposed to a third side and a fourth side of the cavity body, and the third side is opposite to the fourth side.

9. The high-power single-wavelength semiconductor laser having multi-segment grating structure of claim 8, wherein a voltage applied to the plurality of positive electrodes and the plurality of negative electrodes is increased in a longitudinal direction, and the longitudinal direction is extended from the first side to the second side.

10. The high-power single-wavelength semiconductor laser having multi-segment grating structure of claim 1, wherein the electrode structure includes a plurality of positive electrodes and a negative electrode, the plurality of positive electrodes and the negative electrode are respectively disposed to a third side and a fourth side of the cavity body, and the third side is opposite to the fourth side.

11. The high-power single-wavelength semiconductor laser having multi-segment grating structure of claim 10, wherein a voltage applied to the plurality of positive electrodes and the negative electrode is increased in a longitudinal direction, and the longitudinal direction is extended from the first side to the second side.

12. The high-power single-wavelength semiconductor laser having multi-segment grating structure of claim 1, wherein the gain layer is a structure having multiple quantum wells or quantum dots.

13. The high-power single-wavelength semiconductor laser having multi-segment grating structure of claim 1, wherein the anti-reflective facet has a non-zero reflectivity.

14. The high-power single-wavelength semiconductor laser having multi-segment grating structure of claim 1, wherein the longitudinal waveguide structure is extended in a longitudinal direction, and divided into a first section and a second section, the first section includes the reflective facet, one of the plurality of no-corrugation segments and the first sub-grating, the second section includes another one of another one of the plurality of no-corrugation segments, the second sub-grating and the anti-reflective facet, and the longitudinal direction is extended from the first side to the second side.

15. The high-power single-wavelength semiconductor laser having multi-segment grating structure of claim 14, wherein the waveguide structure of the first section and the waveguide of the second section are identical.

16. The high-power single-wavelength semiconductor laser having multi-segment grating structure of claim 14, wherein a width of waveguide structure of the second section is greater than that of the first section.

17. The high-power single-wavelength semiconductor laser having multi-segment grating structure of claim 14, wherein a width of the waveguide structure of the second section varies in the longitudinal direction.

18. The high-power single-wavelength semiconductor laser having multi-segment grating structure of claim 14, wherein a width of the waveguide structure of the second section is increased in the longitudinal direction.

19. A high-power single-wavelength semiconductor laser having multi-segment grating structure, comprising:
a cavity body, having a resonant cavity, a reflective facet and an anti-reflective facet, the resonant cavity being disposed in the cavity body, the reflective facet and the anti-reflective facet being respectively disposed to a first side and a second side of the cavity body, the first side being opposite to the second side;
a gain layer, disposed in the resonant cavity;
an electrode structure, disposed on the cavity body;
a grating layer, disposed in the resonant cavity, including a plurality of sub-gratings and a plurality of no-corrugation segments, the plurality of sub-gratings and the plurality of no-corrugation segments being alternately arranged;
an upper cladding layer and a lower cladding layer, disposed in the resonant cavity, wrapping the gain layer and the grating layer to form a lateral waveguide structure; and
a longitudinal waveguide structure, extending along the resonant cavity between the first side and the second side, connecting the plurality of sub-gratings and the plurality of no-corrugation segments.

20. The high-power single-wavelength semiconductor laser having multi-segment grating structure of claim 19, wherein lengths of the plurality of sub-gratings are the same or different.

21. The high-power single-wavelength semiconductor laser having multi-segment grating structure of claim 19, wherein lengths of the plurality of no-corrugation segments are the same or different.

22. The high-power single-wavelength semiconductor laser having multi-segment grating structure of claim 19, further including a buffer layer disposed between the grating layer and the gain layer, the grating layer being parallel to the gain layer.

23. The high-power single-wavelength semiconductor laser having multi-segment grating structure of claim 19, wherein one of the plurality of sub-gratings is connected to the second side with a passive waveguide segment.

24. The high-power single-wavelength semiconductor laser having multi-segment grating structure of claim 19, wherein the plurality of sub-gratings have the same period.

25. The high-power single-wavelength semiconductor laser having multi-segment grating structure of claim 19, further including a contact layer disposed between the positive electrode and the upper cladding layer.

26. The high-power single-wavelength semiconductor laser having multi-segment grating structure of claim 19, wherein the electrode structure includes a positive electrode and a negative electrode, the positive electrode and the negative electrode are disposed respectively to a third side and a fourth side of the cavity body, and the third side is opposite to the fourth side.

27. The high-power single-wavelength semiconductor laser having multi-segment grating structure of claim 19, wherein the electrode structure includes a plurality of positive electrodes and a plurality of negative electrodes, the plurality of positive electrodes and the plurality of negative electrodes are respectively disposed to a third side and a fourth side of the cavity body, and the third side is opposite to the fourth side.

28. The high-power single-wavelength semiconductor laser having multi-segment grating structure of claim 27, wherein a voltage applied to the plurality of positive electrodes and the plurality of negative electrodes is increased in a longitudinal direction, and the longitudinal direction is extended from the first side to the second side.

29. The high-power single-wavelength semiconductor laser having multi-segment grating structure of claim 19, wherein the electrode structure includes a plurality of positive electrodes and a negative electrode, the plurality of positive electrodes and the negative electrode are respectively disposed to a third side and a fourth side of the cavity body, and the third side is opposite to the fourth side.

30. The high-power single-wavelength semiconductor laser having multi-segment grating structure of claim 29, wherein a voltage applied to the plurality of positive electrodes and the negative electrode is increased in a longitudinal direction, and the longitudinal direction is extended from the first side to the second side.

31. The high-power single-wavelength semiconductor laser having multi-segment grating structure of claim 19, wherein the gain layer is a structure having multiple quantum wells or quantum dots.

32. The high-power single-wavelength semiconductor laser having multi-segment grating structure of claim 19, wherein the anti-reflective facet has a non-zero reflectivity.

33. The high-power single-wavelength semiconductor laser having multi-segment grating structure of claim 19, wherein the longitudinal waveguide structure is extended in a longitudinal direction and includes a first section and a second section, the first section includes the reflective facet, at least one of the plurality of no-corrugation segments and at least one of the plurality of sub-gratings, the second section includes at least one of the plurality of no-corrugation segments, at least one of the plurality of sub-gratings and the anti-reflective facet.

34. The high-power single-wavelength semiconductor laser having multi-segment grating structure of claim 33, wherein the waveguide structure of the first section and the wavelength of the second section are identical.

35. The high-power single-wavelength semiconductor laser having multi-segment grating structure of claim 33, wherein a width of waveguide structure of the second section is greater than that of the first section.

36. The high-power single-wavelength semiconductor laser having multi-segment grating structure of claim 33, wherein a width of the waveguide structure of the second section varies in the longitudinal direction.

37. The high-power single-wavelength semiconductor laser having multi-segment grating structure of claim 33, wherein a width of the waveguide structure of the second section is increased in the longitudinal direction.

38. The high-power single-wavelength semiconductor laser having multi-segment grating structure of claim 19, wherein the longitudinal waveguide structure includes a plurality of sections, one of the plurality of sections includes the reflective facet, at least one of the plurality of no-corrugation segments and at least one of the plurality of sub-gratings, another one of the plurality of sections includes at least one of the plurality of no-corrugation segments, at least one of the plurality of sub-gratings and the anti-reflective facet, one rest of the plurality of sections includes at least one of the plurality of no-corrugation segments and at least one of the plurality of sub-gratings.

39. The high-power single-wavelength semiconductor laser having multi-segment grating structure of claim 38, wherein waveguide structures of the plurality of sections are different to each other.
